(19) United States
(12) Patent Application Publication
(10) Pub. No.: US 2026/0057165 A1
(43) Pub. Date: Feb. 26, 2026

(54) LEGALIZATION OF INTEGRATED CIRCUIT DESIGNS INCORPORATING MULTI-ROW COMPONENTS

(71) Applicant: International Business Machines Corporation, Armonk, NY (US)

(72) Inventors: Benjamin Neil Trombley, Austin, TX (US); Daniel Arthur Gay, Beacon, NY (US)

(21) Appl. No.: 18/814,642

(22) Filed: Aug. 26, 2024

(51) Int. Cl. G06F 30/398

(52) U.S. Cl. CPC G06F 30/398

(57) ABSTRACT

Examples described herein provide a computer-implemented method that includes receiving a desired location for a new component to be added to an existing circuit design having a plurality of existing components arranged on a plurality of rows. The method further includes identifying an overlap between the desired location for the new component and an existing location of at least one of the plurality of existing components. The method further includes repositioning the at least one of the plurality of existing components on a row-by-row basis to accommodate the new component at the desired location. The method further includes generating, based on the repositioning, a modified circuit design that includes the new component located at the desired location. The method further includes causing a circuit to be fabricated using the modified circuit design that includes the plurality of existing components and the new component without overlap of components.

### BACKGROUND

The present disclosure relates to computing environments, and more specifically, to legalization of circuit designs incorporating multi-row components.

A circuit, such as an integrated circuit, is made up of components that work together to perform a function for which the circuit was designed. In some cases, components within an integrated circuit are fabricated on a single piece of semiconductor material (e.g., silicon). Examples of components (also referred to as “cells”) that may be included in an integrated circuit design include, but are not limited to, logic gates, flip-flops, resistors, capacitators, transistors, diodes, inductors, interconnects, operational amplifiers, memory cells, and/or the like, including combinations and/or multiples thereof.

In the context of circuit design, particularly in integrated circuit (IC) design, “legalizing” a circuit design refers to the process of adjusting the placement and layout of circuit components to ensure that the components meet the physical design rules and constraints imposed by the fabrication process.

### SUMMARY

According to an embodiment, a computer-implemented method is provided. The method includes receiving a desired location for a new component to be added to an existing circuit design having a plurality of existing components arranged on a plurality of rows. The method further includes identifying an overlap between the desired location for the new component and an existing location of at least one of the plurality of existing components. The method further includes repositioning the at least one of the plurality of existing components on a row-by-row basis to accommodate the new component at the desired location. The method further includes generating, based on the repositioning, a modified circuit design that includes the new component located at the desired location. The method further includes causing a circuit to be fabricated using the modified circuit design that includes the plurality of existing components and the new component without overlap of components.

Other embodiments described herein implement features of the above-described method in computer systems and computer program products.

The above features and advantages, and other features and advantages, of the disclosure are readily apparent from the following detailed description when taken in connection with the accompanying drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of one or more embodiments described herein are apparent from the following detailed description taken in conjunction with the accompanying drawings in which:

FIG. 1 illustrates a computing environment, according to an embodiment;

FIG. 2 illustrates a flow diagram of a method for legalization of circuit designs incorporating multi-row components, according to an embodiment;

FIG. 3 illustrates a flow diagram of a method for legalization of circuit designs incorporating multi-row components, according to an embodiment;

FIGS. 4A-4H illustrates aspects of legalization of circuit designs incorporating multi-row components, according to an embodiment;

FIG. 5 is a block diagram of a system to perform legalization of circuit designs incorporating multi-row components according to one or more embodiments; and

FIG. 6 is a flow diagram of a method of fabricating an integrated circuit according to one or more embodiments.

### DETAILED DESCRIPTION

One or more embodiments described herein provide for legalization of circuit designs incorporating multi-row components.

In the realm of integrated circuit (IC) design, the placement of circuit components is a step that significantly impacts the performance and manufacturability of the circuit. The process involves arranging a plurality of components within a given footprint, ensuring that each component is positioned in a manner that adheres to design rules and constraints. This task becomes increasingly complex as the number of components and the intricacy of the circuit design grow, which makes achieving optimal placement of components difficult.

Existing placement algorithms may not adequately address the presence of multi-row components, which span multiple rows of the circuit layout. These components introduce additional complexity, as their placement requires careful management to avoid overlaps and ensure that design rules are met. Current methods may terminate or become inefficient when encountering such multi-row components, leading to suboptimal placement and increased design iterations.

One or more embodiments described herein addresses these shortcomings by providing a novel approach to the placement of a plurality of components in a plurality of rows of circuits within a given footprint. According to an embodiment, a method is provided that involves sorting the components according to their initial positions, followed by a legalization process that moves each component from row to row until the optimal placement with minimal movement is found. An algorithm analyzes the circuit row ordering and determines placements in both a first and second direction, ensuring that each row is positioned in an optimal location. The method also considers the presence of multi-row gates, halting the expansion of space gathering for a row until all rows reach the gate, thereby ensuring efficient and effective placement of all components.

Descriptions of various embodiments of the present disclosure are presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

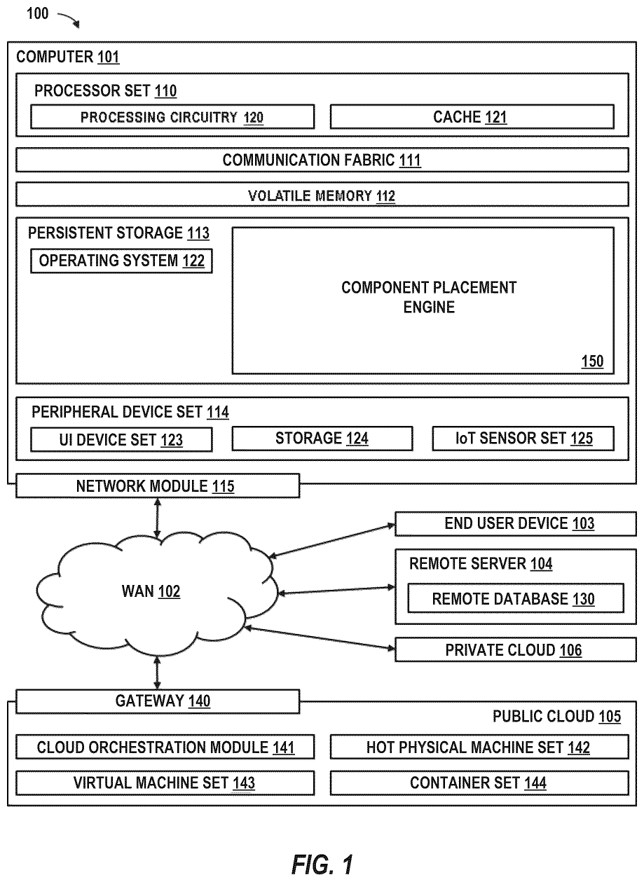

FIG. 1 illustrates a computing environment 100, according to an embodiment. Computing environment 100 contains an example of an environment for the execution of at least some of the computer code involved in performing the inventive methods, such as a component placement engine 150 for generating parameters for statistical timing analysis of a circuit. In addition to the component placement engine 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and the component placement engine 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in the component placement engine 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in the component placement engine 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

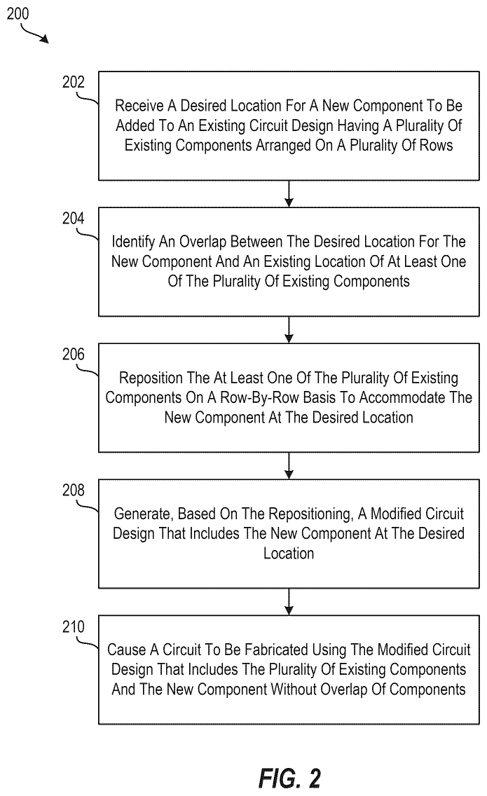

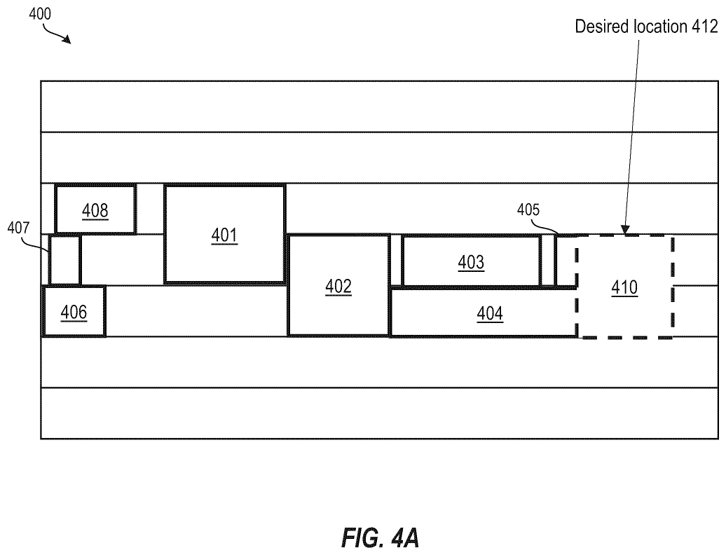

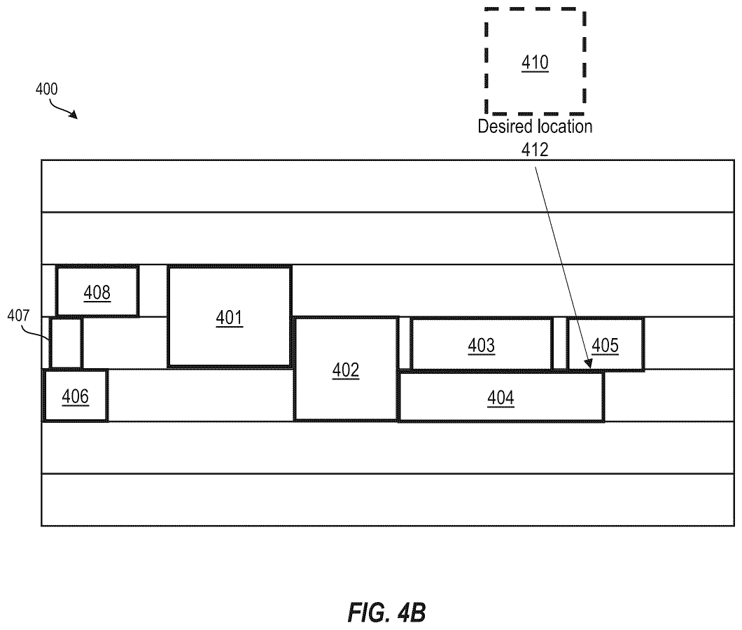

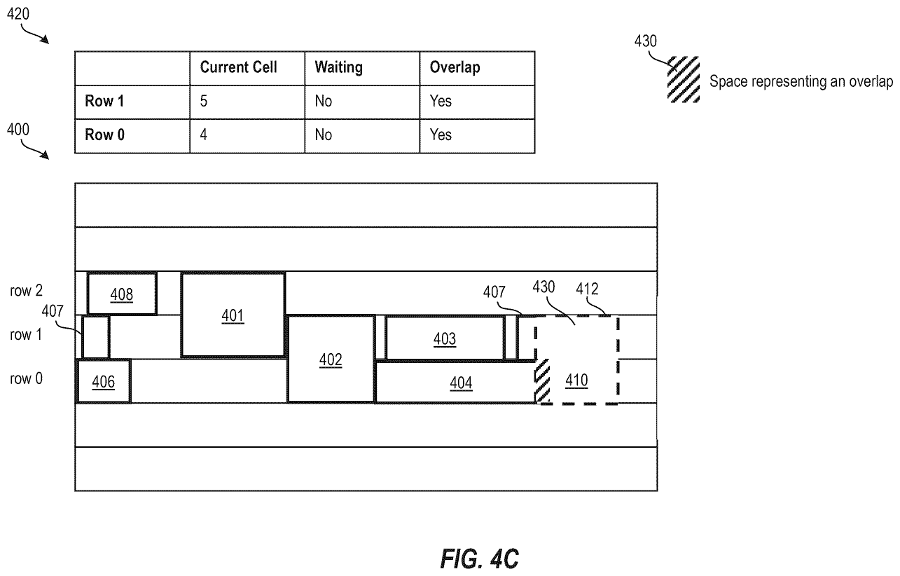

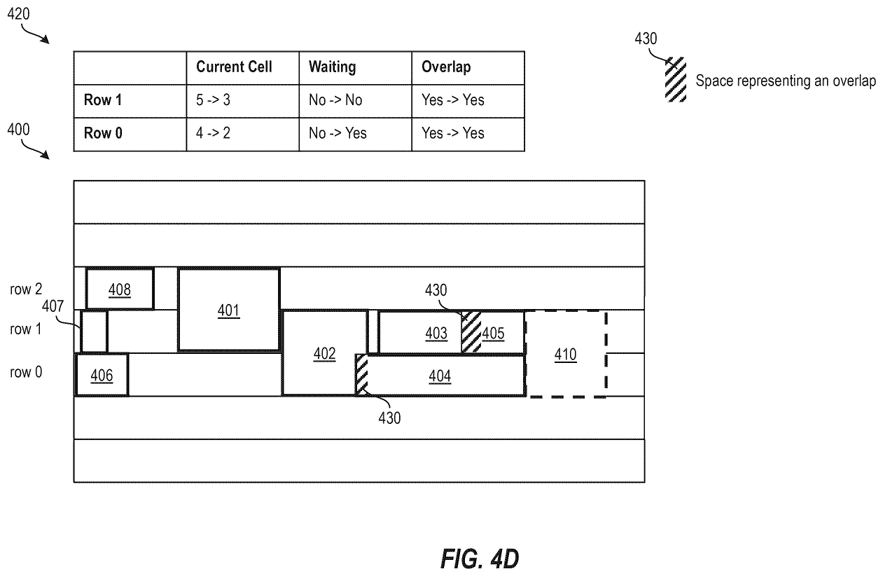

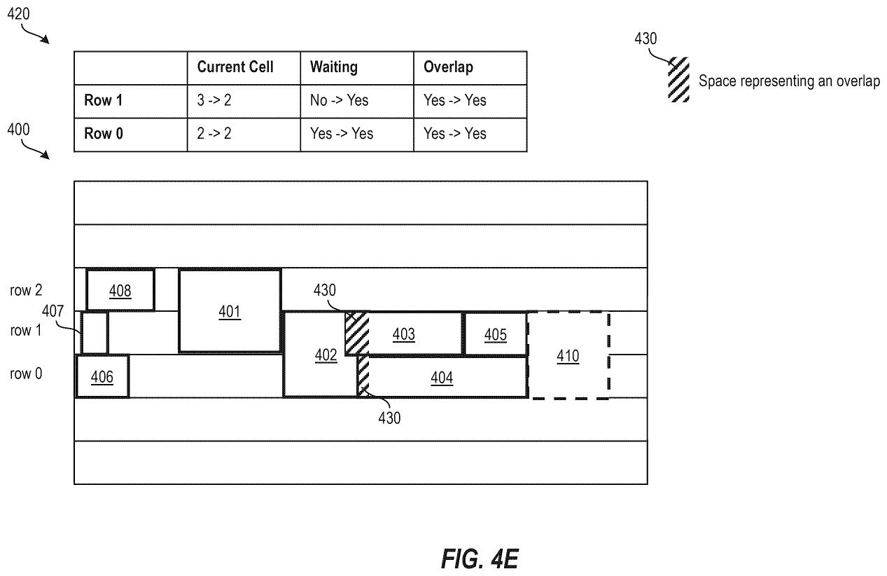

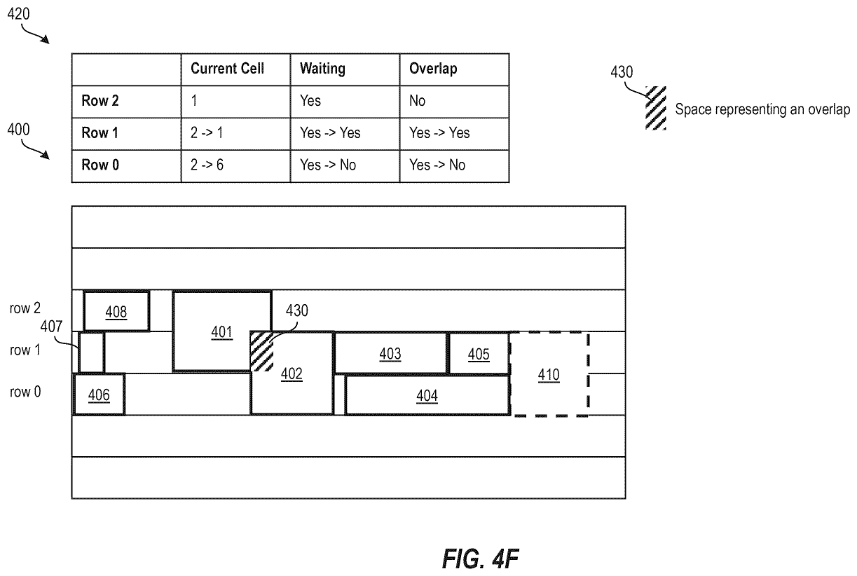

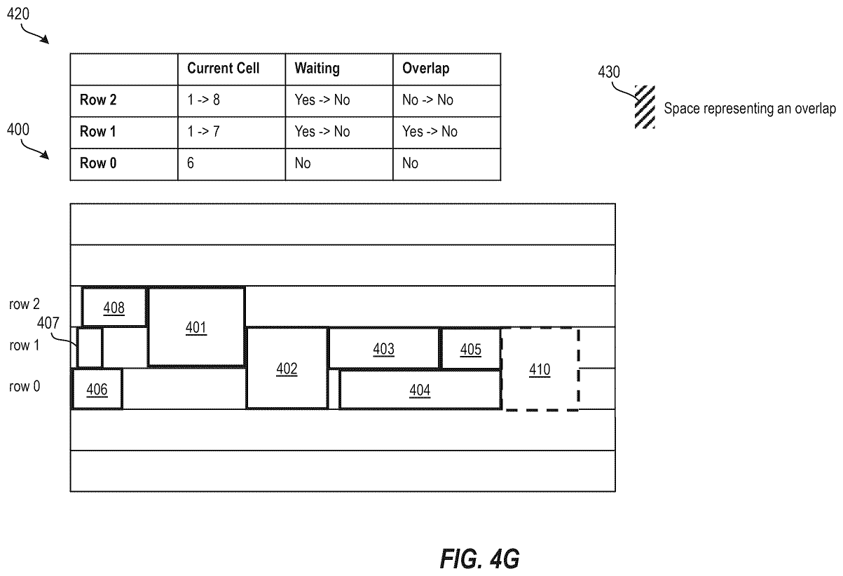

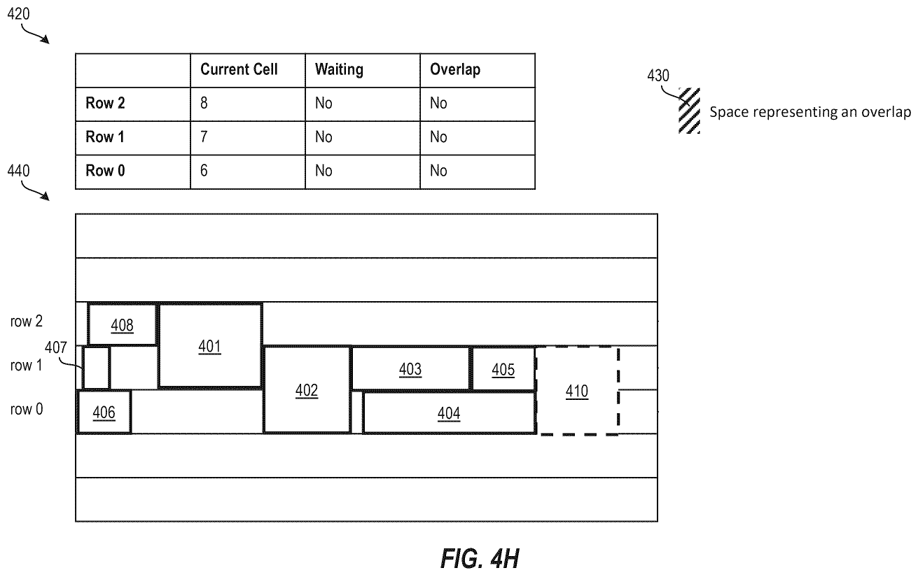

Turning now to FIG. 2, a flow diagram of a method 200 for legalizing circuit designs containing multi-row components is provided, according to an embodiment. The method 200 can be performed by any suitable computing system, device, or environment, such as those described herein. The method 200 is now described with reference to the computing environment 100, and particularly the component placement engine 150, but is not so limited. The method 200 is also described with reference to elements of one or more of FIGS. 4A-4H but is not so limited.

The method 200 begins at block 202, where the component placement engine 150 receives a desired location for a new component to be added to an existing circuit design having a plurality of existing components arranged on a plurality of rows. For example, FIG. 4A shows a circuit layout 400 having existing components 401, 402, 403, 404, 405, 406, 407, 408 and a desired location 412 for a new component 410 to be placed. With continued reference to FIG. 2, this step of the method 200 involves obtaining the specific coordinates or area within the circuit layout where the new component is intended to be placed. The desired location guides the subsequent steps of the method, ensuring that the new component is integrated into the design accurately and efficiently. By receiving a desired location for a new component to be added to an existing circuit design, the method ensures that the placement process begins with a clear target, facilitating precise and efficient component integration.

At block 204, the component placement engine 150 identifies an overlap between the desired location for the new component and an existing location of at least one of the plurality of existing components. This involves analyzing the current layout to detect any conflicts where the desired location of the new component intersects with the space occupied by existing components. Identifying overlaps early in the process is useful for reducing or preventing design rule violations and ensuring that the new component can be accommodated.

At block 206, the component placement engine 150 repositions the at least one of the plurality of existing components on a row-by-row basis to accommodate the new component at the desired location. This step involves systematically adjusting the positions of the existing components to create space for the new component. The repositioning is performed on a row-by-row basis, ensuring that adjustments are made in a controlled and systematic manner. This approach minimizes the movement of existing components, reducing the risk of introducing new overlaps or other issues, and maintains the integrity of the original design as much as possible.

At block 208, the component placement engine 150 generates, based on the repositioning, a modified circuit design that includes the new component located at the desired location. This involves creating an updated layout that reflects the new positions of the existing components and the integration of the new component. The modified circuit design ensures that the new component is seamlessly incorporated into the layout, ready for the next stages of the design process, such as verification and fabrication.

At block 210, the component placement engine 150 causes a circuit to be fabricated using the modified circuit design. The modified design includes the plurality of existing components (e.g., the components 401-408) as well as the new component (e.g., the new component 410) without overlaps between the existing components and/or the new component. The fabricating involves translating the optimized layout into a physical integrated circuit. The fabrication process includes creating masks for lithography, processing the wafer, and performing photolithography and etching. The final product is a physical integrated circuit that benefits from the optimized placement, resulting in improved performance and manufacturability.

Additional processes also may be included, and it should be understood that the processes depicted in FIG. 2 represent illustrations, and that other processes may be added or existing processes may be removed, modified, or rearranged without departing from the scope of the present disclosure. It should also be understood that the processes depicted in FIG. 2 may be implemented as programmatic instructions stored on a non-transitory computer-readable storage medium that, when executed by a processor (e.g., the processor set 110, the processing circuitry 120) of a computing system (e.g., the computer 101), cause the processor to perform the processes described herein.

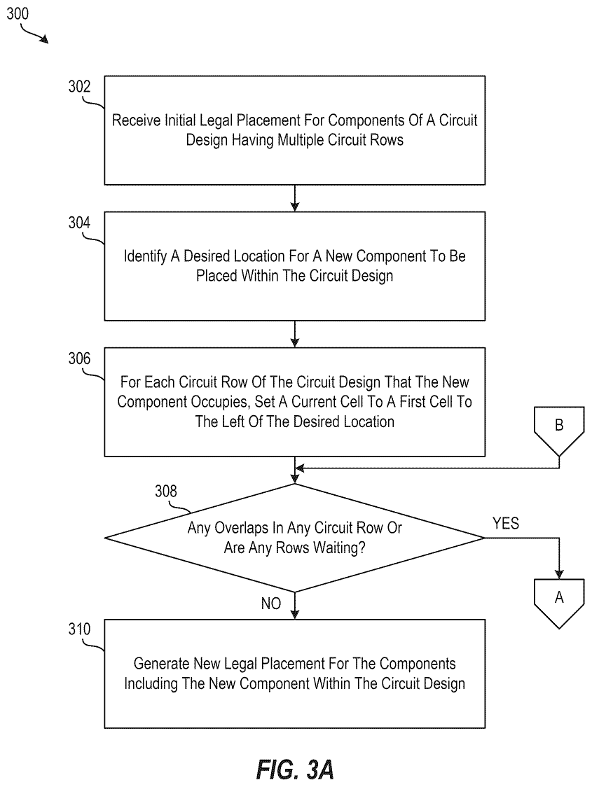

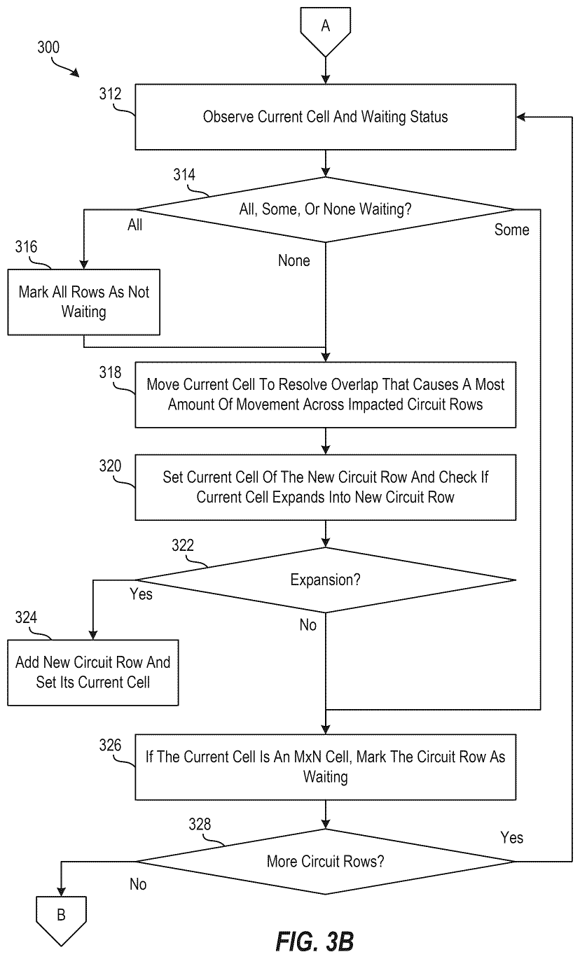

FIGS. 3A and 3B together illustrate a flow diagram of a method 300 for legalizing circuit designs containing multi-row components, according to an embodiment. The method 300 can be performed by any suitable computing system, device, or environment, such as those described herein. The method 300 is now described with reference to the computing environment 100, and particularly the component placement engine 150, but is not so limited. The method 300 is also described with reference to elements of one or more of FIGS. 4A-4H but is not so limited.

FIG. 3A illustrates a method 300 for legalizing circuit designs containing multi-row components according to an embodiment. The method 300 begins at block 302, where the component placement engine 150 receives an initial legal placement for components of a circuit design having multiple circuit rows. This step involves obtaining the initial positions of the components within the circuit layout, ensuring that each component is placed in accordance with design rules and constraints. The initial legal placement serves as the starting point for the subsequent steps of the method 300, providing a baseline for further adjustments and optimizations.

At block 304, the component placement engine 150 identifies a desired location (e.g., the desired location 412 of FIGS. 4A and 4B) for a new component (e.g., the new component 410 of FIGS. 4A-4H) to be placed within the circuit design. This step involves determining the specific coordinates or area within the circuit layout where the new component is intended to be added. The desired location guides the subsequent steps of the method, ensuring that the new component is integrated into the design accurately and efficiently. As shown in FIG. 4A, the desired location 412 for the new component 410 is identified within the existing circuit layout 400.

At block 306, the component placement engine 150, for each circuit row of the circuit design (e.g., row 0, row 1, row 2, etc.) that the new component occupies, set a current existing component to a first existing component to the left of the desired location. This involves selecting the initial position within each row that will be evaluated for potential overlaps and adjustments. By setting a current existing component to a first existing component to the left of the desired location, the method ensures that the placement process begins with a clear reference point, facilitating precise and efficient component integration. FIG. 4B illustrates the initial setting of the current existing component for each row in the circuit layout 400.

At block 308, the component placement engine 150, determines if there are any overlaps in any circuit row or if any rows are waiting. This step involves analyzing the current layout to detect any conflicts where the new component's desired location intersects with the space occupied by existing components. Identifying overlaps early in the process is useful for preventing design rule violations and ensuring that the new component can be accommodated without creating overlaps within the existing layout. The concept of waiting and whether any rows are waiting is described in more detail herein with reference to data structure 420 of FIGS. 4C-4H.

If it is determined that no overlaps in any circuit row and that no rows are waiting (block 308 “NO”), the method 300 proceeds to block 310, where the component placement engine 150, generates a new legal placement for the components, including the new component, within the circuit design. This involves creating an updated layout that reflects the new positions of the existing components and the integration of the new component. The new legal placement ensures that the new component is seamlessly incorporated into the layout without overlaps, ready for the next stages of the design process, such as verification and fabrication. FIG. 4C shows the identification of a space representing an overlap 430 between the desired location 412 and existing components 401 and 404, for example.

If it is determined that overlaps in any circuit row exist and/or that rows are waiting (block 308 “YES”), the method 300 proceeds to block 312 (see FIG. 3B). Blocks 312-326 are now described and are performed on a per-row basis. That is, the blocks 312-326 are performed for each circuit row iteratively.

At block 312, the component placement engine 150 observes the current existing component and waiting status. This step involves monitoring the current position of the existing component being evaluated and determining whether any rows are in a waiting state due to overlaps or other constraints. Observing the current existing component and waiting status ensures that the method 300 can dynamically adjust the placement process based on real-time conditions within the circuit layout.

At block 314, the component placement engine 150 determines if all, some, or none of the rows are waiting. This step involves categorizing the rows based on their waiting status, which helps in prioritizing the adjustments needed to resolve overlaps and accommodate the new component. By determining if all, some, or none of the rows are waiting, the method 300 can efficiently allocate resources and focus on the areas of the layout.

If all the rows are waiting (block 314 “All”), the component placement engine 150 marks all rows as not waiting. This involves resetting the waiting status of all rows to ensure that the placement process can proceed without unnecessary delays. Marking all rows as not waiting helps in maintaining a streamlined and efficient placement process, reducing the risk of bottlenecks and other issues. The method 300 then advances to block 318.

If none of the rows are waiting (block 314 “Some”), the method 300 advances to block 318.

At block 318, the component placement engine 150 moves the current existing component to resolve the overlap that causes the most amount of movement across impacted circuit rows. This step involves adjusting the position of the current existing component to eliminate overlaps, prioritizing the adjustments that result in the most significant movement. By moving the current existing component to resolve the overlap that causes the most amount of movement, the method 300 ensures that the placement process is both effective and efficient, minimizing the overall disruption to the layout.

At block 320, the component placement engine 150 sets the current existing component of the new circuit row and checks if the current existing component expands into a new circuit row. This involves updating the position of the current existing component within the new row and determining whether the component's placement extends into additional rows, which are then to be added to a data structure for managing component placement. Setting the current existing component of the new circuit row and checking for expansion ensures that the method 300 can accurately track and manage the placement of multi-row components.

At block 322, the component placement engine 150 determines if there is an expansion of the current existing component into a new circuit row. This step involves evaluating whether the current existing component's placement expands into new rows to accommodate the component. Determining if there is an expansion helps in managing the layout's complexity and ensuring that components are placed within the available space.

If expansion is determined (block 322 “Yes”), the method 300 proceeds to block 324, where the component placement engine 150 adds the new circuit row to the data structure and sets the current existing component. This involves adding the new row to the data structure (e.g., the data structure 420 shown in FIGS. 4C-4H) and setting the initial position of the current existing component within this row.

If no expansion is determined (block 322 “No”), the method 300 proceeds to block 326, where the component placement engine 150 marks the circuit row as waiting if the current existing component is an M×N existing component, where M and N are integers, and N is greater than 1. This step involves identifying multi-row components and marking the corresponding rows as waiting to ensure that their placement is managed. Marking the circuit row as waiting helps in preventing overlaps and ensuring that multi-row components are integrated seamlessly into the layout.

At block 328, the component placement engine 150 determines whether there are more circuit rows. This involves evaluating whether additional rows need to be added to the data structure to complete the placement of the new component. If so (block 328 “Yes”), the method 300 returns to block 312. If not (block 328 “No”), the method 300 returns to block 308 (FIG. 3A) and continues.

Additional processes also may be included, and it should be understood that the processes depicted in FIG. 3 represent illustrations, and that other processes may be added or existing processes may be removed, modified, or rearranged without departing from the scope of the present disclosure. It should also be understood that the processes depicted in FIG. 3 may be implemented as programmatic instructions stored on a non-transitory computer-readable storage medium that, when executed by a processor (e.g., the processor set 110, the processing circuitry 120) of a computing system (e.g., the computer 101), cause the processor to perform the processes described herein.

FIG. 4A illustrates a circuit layout 400 containing multiple components. The circuit layout 400 includes existing components 401, 402, 403, 404, 405 406, 407, and 408, as well as a new component 410. The desired location 412 for the new component 410 is identified within the existing circuit layout 400. The existing components are arranged in a manner that may require adjustment to accommodate the new component 410 at the desired location 412.

FIG. 4B further details the circuit layout 400, showing the existing components 401, 402, 403, 404, 405, 406, 407, and 408, along with the new component 410. The desired location 412 for the new component 410 is highlighted, indicating where the new component 410 is intended to be placed within the existing layout. By comparison with FIG. 4A, it is evident that the existing component 405 introduces further complexity in managing the placement of the components within the circuit layout 400 because the existing components 404 and 405 directly overlap, and therefore interfere with, the desired location 412 for the new component 410.

FIGS. 4C-4H introduce a data structure 420 used to manage the placement process by storing information regarding which existing component is the current existing component (“current cell”), whether that existing component is waiting (“waiting”), and whether an overlap exists (“overlap”). The circuit layout 400 includes the new component 410 and existing components 401, 402, 403, 404, 405 406, 407, and 408. The data structure 420 helps track overlaps and waiting statuses of the components. The overlap 430 between the desired location 412 and existing components is identified, indicating areas where adjustments are to be made to accommodate the new component 410.

In FIG. 4C, circuit row 0 is added to the data structure 420 due to overlap with existing component 404, and circuit row 1 is added to the data structure 420 due to overlap with existing component 405.

In FIG. 4D, existing component 404 is moved left to avoid overlap with the new component 410, and a next component (e.g., the existing component 402, which is an M×N component), is marked as “waiting” in the data structure 420. Existing component 405 is moved to avoid overlap, and a next component is designated as existing component 403, which is not waiting.

In FIG. 4E, nothing happens in row 0 because row 0 is waiting on existing component 402, and the rows containing existing component 402 are in a waiting state as shown by the data structure 420. Existing component 403 moves to avoid overlap 430, and the next component is an M×N component, namely the existing component 402, so row 1 becomes waiting.

In FIG. 4F, for row 0, the existing component 402 is moved based on the overlap in row 1 as the overlap there was larger relative to the other rows (e.g., row 1), and the existing component 402 is marked as a next component for row 0. For row 1, existing component 402 is moved based on the overlap in row 1, as the overlap was larger here than in other rows (e.g., row 0), and existing component is marked as a next component for row 1. Existing component 401 is an M×N component, so row 1 needs to wait. Row 2 is added to the data structure 420 due to the overlap at existing component 401, which is an M×N existing component, so row 2 needs to wait.

In FIG. 4G, for row 0, there is nothing to do because there is no overlap. For row 1, existing component 401 is moved to avoid overlap on this row as it had a the largest overlap (relative to other rows), and existing component 407 is marked as a next component for row 1. For row 2, existing component 401 is moved based on the overlap that exists in row 1, and existing component 408 is marked as a next component for row 2.

In FIG. 4H, for each of rows 0, 1, and 2, there is nothing to do because there is no overlap or waiting. Thus, FIG. 4H represents a modified circuit design 440 that includes the plurality of existing components and the new component without overlap of components.

It should be appreciated that the embodiment of FIGS. 4A-4H show and describe shifting exiting components in a leftward direction; however, this is shown merely as an example, and that the embodiments described herein can be used to shift existing components in either left or right directions as desired to accommodate a new component.

One or more embodiments described herein improves the functioning of a computer by optimizing the placement of components in IC designs, particularly those incorporating multi-row components. This optimization process enhances the computer's ability to handle complex circuit layouts efficiently, leading to several key improvements, which are now described in more detail.

By ensuring that components are placed in an optimal manner, one or more embodiments reduces signal delays and improves the overall speed of the circuit. This results in faster processing times and better performance of the computer systems utilizing these circuits.

One or more embodiments minimizes the movement of existing components during the legalization process, which reduces the computational resources required for placement adjustments. This leads to more efficient use of the computer's processing power and memory, allowing the computer to handle larger and more complex designs without significant performance degradation.

Existing placement algorithms may struggle with multi-row components, leading to multiple design iterations to achieve a legal placement. One or more embodiments addresses this issue by providing a systematic approach to handle multi-row components, thereby reducing the number of iterations needed. This accelerates the design process and reduces the time-to-market for new IC designs.

By generating a modified circuit design that adheres to physical design rules and constraints, one or more embodiments ensures that the final layout is manufacturable. This reduces the likelihood of errors during fabrication, leading to higher yield rates and lower production costs.

Embodiments described herein for handling multi-row components and optimizing placement are scalable, making them suitable for a wide range of circuit complexities and sizes. This scalability ensures that the computer can efficiently manage both small and large-scale IC designs.

One or more embodiments leverages a data structure to track overlaps and waiting statuses, enabling more precise and controlled adjustments. This targeted approach to repositioning components ensures that computational resources are used effectively, avoiding unnecessary calculations and movements.

Overall, one or more embodiments enhances a computer's ability to design and optimize integrated circuits, leading to improved performance, efficiency, and manufacturability of the final products. These improvements contribute to the development of more advanced and reliable electronic devices, benefiting various industries and applications.

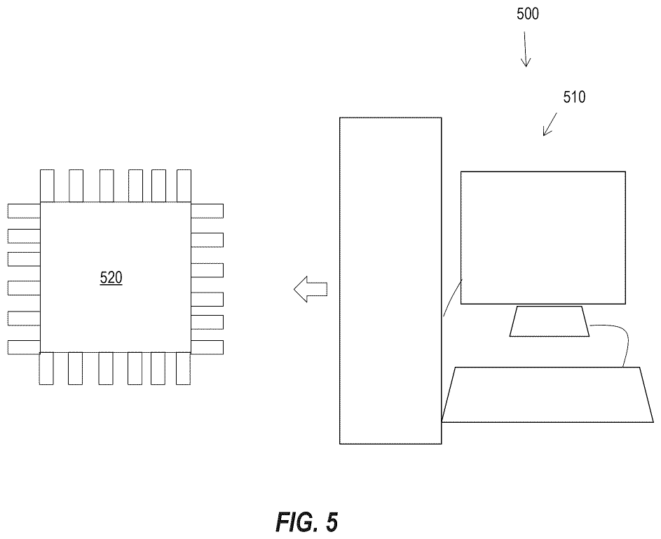

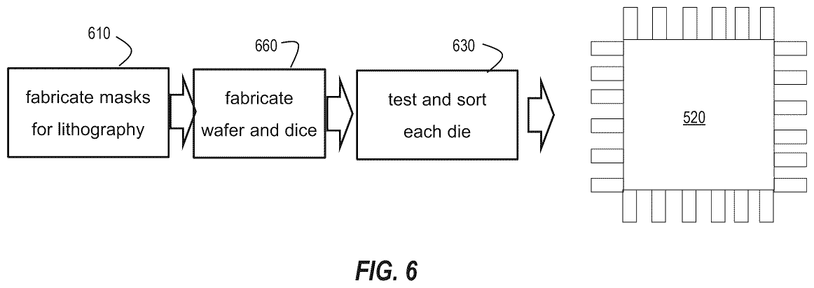

FIG. 5 is a block diagram of a system 500 to perform circuit design optimization according to one or more embodiments. The system 500 includes processing circuitry 510 used to generate the circuit design that is ultimately fabricated into an integrated circuit 520. The steps involved in the fabrication of the integrated circuit 520 are well-known and briefly described herein. Once the physical layout is finalized, based, in part, on the circuit design optimization according to one or more embodiments, the finalized physical layout is provided to a foundry. Masks are generated for each layer of the integrated circuit based on the finalized physical layout. Then, the wafer is processed in the sequence of the mask order. The processing includes photolithography and etch. This is further discussed with reference to FIG. 6.

Particularly, FIG. 6 is a flow diagram of a method 600 of fabricating an integrated circuit according to one or more embodiments. Once the physical design data is obtained, based, in part, on performing circuit design optimization as described herein, the integrated circuit 520 can be fabricated according to known processes that are generally described with reference to FIG. 6. Generally, a wafer with multiple copies of the final design is fabricated and cut (i.e., diced) such that each die is one copy of the integrated circuit 520. At block 610, the processes include fabricating masks for lithography based on the finalized physical layout. At block 620, fabricating the wafer includes using the masks to perform photolithography and etching. Once the wafer is diced, testing and sorting each die is performed, at block 630, to filter out any faulty die.

While the foregoing is directed to embodiments of the present disclosure, other and further embodiments of the present disclosure may be devised without departing from the basic scope thereof, and the scope thereof is determined by the claims that follow.

What is claimed is:

1. A computer-implemented method comprising:
receiving a desired location for a new component to be added to an existing circuit design having a plurality of existing components arranged on a plurality of rows;
identifying an overlap between the desired location for the new component and an existing location of at least one of the plurality of existing components;
repositioning the at least one of the plurality of existing components on a row-by-row basis to accommodate the new component at the desired location;
generating, based on the repositioning, a modified circuit design that includes the new component located at the desired location; and
causing a circuit to be fabricated using the modified circuit design that includes the plurality of existing components and the new component without overlap of components.

2. The computer-implemented method of claim 1, wherein the repositioning is based at least in part on a waiting status of the at least one of the plurality of existing components.

3. The computer-implemented method of claim 2, wherein the waiting status is stored in a data structure.

4. The computer-implemented method of claim 1, wherein the repositioning comprises:
repositioning a first subset of components of the plurality of existing components that are located in a first row; and
repositioning a second subset of components of the plurality of existing components that is located in a second row.

5. The computer-implemented method of claim 4, wherein the first subset of components comprises at least two components.

6. The computer-implemented method of claim 4, wherein the second subset of components comprises at least two components.

7. The computer-implemented method of claim 1, wherein the repositioning comprises shifting the at least one of the plurality of existing components left relative to the desired location for the new component.

8. The computer-implemented method of claim 1, wherein the repositioning comprises shifting the at least one of the plurality of existing components right relative to the desired location for the new component.

9. The computer-implemented method of claim 1, wherein the plurality of existing components comprises at least one multi-row component that spans at least two of the plurality of existing components.

10. A system comprising:
a memory comprising computer readable instructions; and
a processing device for executing the computer readable instructions, the computer readable instructions controlling the processing device to perform operations comprising:
receiving a desired location for a new component to be added to an existing circuit design having a plurality of existing components arranged on a plurality of rows;
identifying an overlap between the desired location for the new component and an existing location of at least one of the plurality of existing components;
repositioning the at least one of the plurality of existing components on a row-by-row basis to accommodate the new component at the desired location;
generating, based on the repositioning, a modified circuit design that includes the new component located at the desired location; and
causing a circuit to be fabricated using the modified circuit design that includes the plurality of existing components and the new component without overlap of components.

11. The system of claim 10, wherein the repositioning is based at least in part on a waiting status of the at least one of the plurality of existing components.

12. The system of claim 11, wherein the waiting status is stored in a data structure.

13. The system of claim 10, wherein the repositioning comprises:
repositioning a first subset of components of the plurality of existing components that are located in a first row; and
repositioning a second subset of components of the plurality of existing components that is located in a second row.

14. The system of claim 13, wherein the first subset of components comprises at least two components.

15. The system of claim 13, wherein the second subset of components comprises at least two components.

16. The system of claim 10, wherein the repositioning comprises shifting the at least one of the plurality of existing components left relative to the desired location for the new component.

17. The system of claim 10, wherein the repositioning comprises shifting the at least one of the plurality of existing components right relative to the desired location for the new component.

18. The system of claim 10, wherein the plurality of existing components comprises at least one multi-row component that spans at least two of the plurality of existing components.

19. A computer program product comprising:
a set of one or more computer-readable storage media;
program instructions, collectively stored in the set of one or more storage media, for causing a processor set to perform the following computer operations:
receiving a desired location for a new component to be added to an existing circuit design having a plurality of existing components arranged on a plurality of rows;
identifying an overlap between the desired location for the new component and an existing location of at least one of the plurality of existing components;
repositioning the at least one of the plurality of existing components on a row-by-row basis to accommodate the new component at the desired location;
generating, based on the repositioning, a modified circuit design that includes the new component located at the desired location; and
causing a circuit to be fabricated using the modified circuit design that includes the plurality of existing components and the new component without overlap of components.

20. The computer program product of claim 19, wherein the repositioning is based at least in part on a waiting status of the at least one of the plurality of existing components.
